(19) United States
(12) Patent Application Publication
(10) Pub. No.: US 2010/0059258 A1
(43) Pub. Date: Mar. 11, 2010

(54) Ferrite Mosaic and Magnetic Core Structure for Passive Substrate for Switched-Mode Power Supply Module

(76) Inventors: Xu Yang, Xi'an (CN); Jianing Wang, Xi'an (CN); Zhaoan Wang, Xi'an (CN); Bob Yuan, Xi'an (CN); Qiaoliang Chen, Xi'an (CN)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 12/503,237

(22) Filed: Jul. 15, 2009

(30) Foreign Application Priority Data
Aug. 19, 2008 (CN) 200810150673.X
Apr. 3, 2009 (CN) 200910021868.9

(51) Int. Cl. H05K 1/09; B32B 3/30; H01F 3/00

(52) U.S. Cl. 174/257; 428/167; 335/297

(57) ABSTRACT

The present invention relates to switched-mode power supply module and discloses a ferrite mosaic and a magnetic core structure for passive substrate for switched-mode power supply module. The ferrite mosaic includes a supporting plate and numbers of ferrite units stuck on the supporting plate, with each ferrite unit being rectangular. Wherein the ferrite mosaic comprises air-gaps defined between the ferrite units and ferrite glue polymer composites cured in air-gaps, and the magnetic core structure is finished after cutting, laminating and assembling said ferrite mosaics.

### BACKGROUND OF THE INVENTION

1. Field of the Invention

The present invention relates generally to switched-mode power supply modules and more particularly to a ferrite mosaic and a magnetic core structure which are applied in passive substrate for switched-mode power supply module.

2. Description of the Related Art

The trend in the design of switched-mode power supply modules improves toward several targets as high power density, ultra-thin thickness and low cost. Power electronic components, in particular magnetic components, having ultra-thin size are the key to the achievement of miniaturization and flat of power-supply modules. Further, the magnetic components such as inductors and transformers embedded in PCB (printed circuit board) could achieve ultra-thin power converter with technology trends.

China patent No. CN101018446 has disclosed that a method for producing passive substrate compatible with PCB (printed circuit board) process. However, the cores for magnetic components embedded into the passive substrate are preferably flat ferrite cores which are cut via diamond cutting machine from commercial magnetic cores or sintered via sintering furnace in accordance with the design needs. Two defects exist in this method: first, it is not conducive to modularity and standardization of the magnetic core and causes a decrease of efficiency of production and an increase of cost; second, in passive integrated module, because of the flat magnetic core of inductors, the gap aspect ratio is so high that results great fringing magnetic field due to fringing effect of the gap. A conventional inductor design would be no longer applicable. Even though adding a correction factor to an inductor design formula to reduce design errors, the fringing field around the gap due to fringing effect would cause that current distribution in winding is not uniform. And it further causes additional copper losses.

In addition, the flat magnetic core has a larger surface area and a thinner thickness, so that while the flat magnetic core is embedded into the passive substrate, it is easy to be broken and cause a higher defect rate.

Regarding to method of the flat magnetic core structure, it has been suggested to produce magnetic core structure by ferrite polymer composites. The ferrite polymer composites are produced by mixing ferrite powder and polymers as to form polymer composites. The average permeability of the ferrite polymer is adjustable by changing the ratio of the ferrite powder to polymers. Although distributed gap in the core made by ferrite polymer composites could reduce the fringing field as to reduce the copper losses, the average permeability of said material is too low and the core loss is high. Hence, it does not suit for high-frequency and high-efficiency switched-mode power supply module.

### SUMMARY OF THE INVENTION

Aspects of the present invention address one or more of the issues mentioned above, thereby providing a magnetic core structure for passive substrate of switched-mode power supply module. Technology trends of this invention are improvement of modularity and standardization of design of the magnetic core, upgrading the efficiency and reducing production costs; at the same time, fringing field around air-gaps of the magnetic core could be reduced and copper losses are decreased; further, while the magnetic core is embedded into the passive substrate, the magnetic core is not easy to be broken as to cause a higher defect rate.

Aspect 1: a ferrite mosaic for passive substrate of switched-mode power supply module, the ferrite mosaic comprises a supporting plate and numbers of ferrite units stuck on the supporting plate. Each of the ferrite units is rectangular.

Said ferrite mosaic further comprises ferrite glue polymer composites cured in air-gaps between the ferrite units.

Said ferrite glue polymer composites are a mixture of ferrite powders and epoxy polymer resin or a mixture of ferrite powders and organic silicon polymer.

Said supporting plate is a plastic film or insulation paper or PCB plate or ferrite polymer film.

Said each ferrite unit has upper and lower surfaces which are both square.

Said ferrite units define transverse and longitudinal air-gaps therebetween, and width of each transverse air-gap is equal to that of each longitudinal air-gap.

Aspect 2: a magnetic core structure for passive substrate of switched-mode power supply module, the magnetic core structure is finished after cutting, laminating and assembling the ferrite mosaics discussed in aspect 1.

The ferrite units which have standard rectangular shape are formed by sintering or cutting ferrite. And then the ferrite units are stuck onto the supporting plate, and a magnetic core structure having the desired shape and size is formed after cutting, laminating and assembling the ferrite mosaics which are consisted of the ferrite units and the supporting plate. It improves modularity and standardization of the design of the magnetic core, makes production of the magnetic core much easier, reduces the cost and increases the productivity. Simultaneously, ferrite glue polymer composites are cured in air-gaps between the ferrite units. The ferrite glue polymer composite is a mixture of ferrite powders and epoxy polymer resin or a mixture of ferrite powders and organic silicon polymer. The ferrite glue polymer composites have an average permeability more than 1, so each equivalent air gap length between the ferrite units is decreased as to reduce reluctance and get a high-inductance magnetic core.

Moreover, the concentrated air gap of the magnetic core could be dispersed equally to whole magnetic circuit as to reduce the copper losses caused by strong fringing field. This invention discloses that numbers of small area magnetic units are joined together to form a large area magnetic core, and while the magnetic core is embedded into passive substrate, it would not be broken easily as to causes a higher defect rate.

### BRIEF DESCRIPTION OF THE DRAWINGS

The present invention will be described via detailed illustration of the preferred embodiment referring to the drawings.

FIG. 1 is a perspective view of one ferrite mosaic according to the preferred embodiment of the present invention.

FIG. 2 is a perspective view of a single layer of ferrite mosaic with one surface covered over by ferrite units.

FIG. 3 is a functional flow diagram in accordance with the preferred embodiment of the present invention, illustrating the process to form a single layer ferrite mosaic shown in FIG. 2.

FIG. 4 is an exploded view of a horizontal magnetic core structure without center pole in accordance with the preferred embodiment of the present invention.

FIG. 5 is an exploded view of a horizontal magnetic core structure with a center pole in accordance with the preferred embodiment of the present invention.

FIG. 6(a) is an exploded view of a single layer horizontal magnetic core structure with numbers of center poles in accordance with the preferred embodiment of the present invention.

FIG. 6(b) is a functional flow diagram in accordance with the preferred embodiment of the present invention, illustrating the installation process of the magnetic core structure shown in FIG. 6(a).

FIG. 7(a) is an exploded view of a multi-layer horizontal magnetic core structure without center pole in accordance with the preferred embodiment of the present invention.

FIG. 7(b) is a functional flow diagram in accordance with the preferred embodiment of the present invention, illustrating the installation process of the magnetic core structure shown in FIG. 7(a).

FIG. 8(a) is an exploded view of a vertical magnetic core structure without center pole in accordance with the preferred embodiment of the present invention.

FIG. 8(b) is a functional flow diagram in accordance with the preferred embodiment of the present invention, illustrating the installation process of the magnetic core structure shown in FIG. 8(a).

FIG. 9 is a functional flow diagram for illustrating an installation process of a horizontal magnetic core structure without center pole with PCB as the supporting plate in accordance with the preferred embodiment of the present invention.

FIG. 10 is a functional flow diagram for illustrating an installation process of a horizontal magnetic core structure with numbers of center poles in accordance with the preferred embodiment of the present invention which has equivalent small air-gaps.

FIG. 11 is a functional flow diagram for illustrating an installation process of a vertical magnetic core structure without of center pole in accordance with the preferred embodiment of the present invention which has equivalent small air-gaps.

### DETAILED DESCRIPTION OF THE PREFERRED EMBODIMENT

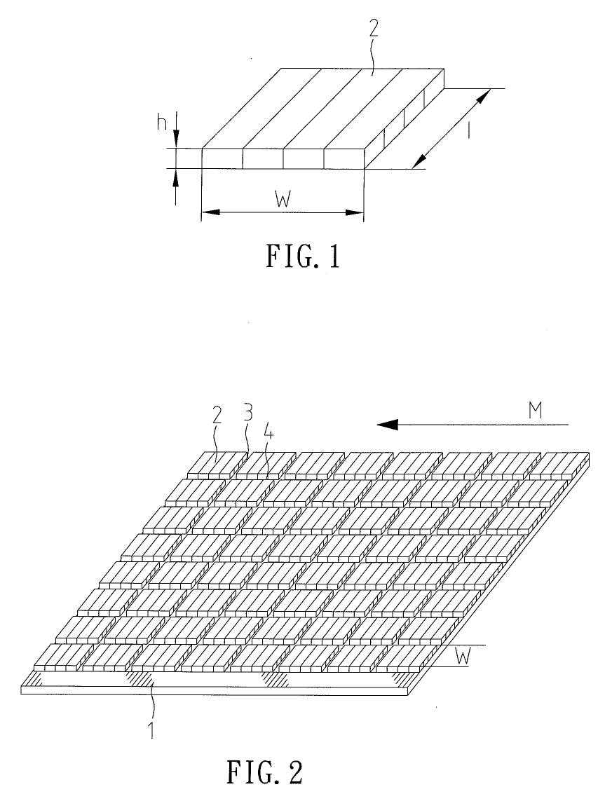

Referring to FIG. 1, one ferrite unit 2 in accordance with the preferred embodiment of the present invention is able to be made by sintering or cutting. The dimensions of the ferrite unit 2 include length “1”, width “w” and height “h”. The ferrite unit 2 has upper and lower surfaces which are both rectangular, in the best embodiment, are both square.

Referring to FIG. 2, it shows a supporting plate 1 which has an upper surface and numbers of ferrite units 2 covers over the upper surface of the supporting plate 1. In this case, there're 8 times 8 or 64 ferrite units 2 stuck to the upper surface of the supporting plate 1 with binder. Depending on design requirements, the needed numbers of ferrite units 2 are changeable. As shown in the drawings, the direction of the magnetic field is shown by an arrow M. Transverse and longitudinal air-gaps 3, 4 are provided between the ferrite units 2; the transverse air-gaps 3 are perpendicular to the arrow M and the longitudinal air-gaps 4 are provided along the arrow M. An impact of the average permeability of magnetic core from the longitudinal air-gaps 4 between the ferrite units 2 can be ignored. The average permeability of magnetic core is adjustable by controlling width of the transverse air-gaps 3 between the ferrite units 2. Specifically, if the aspect ratio of gaps is adjusted to be in the range between 0.1 and 0.01, the fringing field of the magnetic field around the transverse air-gaps 3 could be greatly reduced.

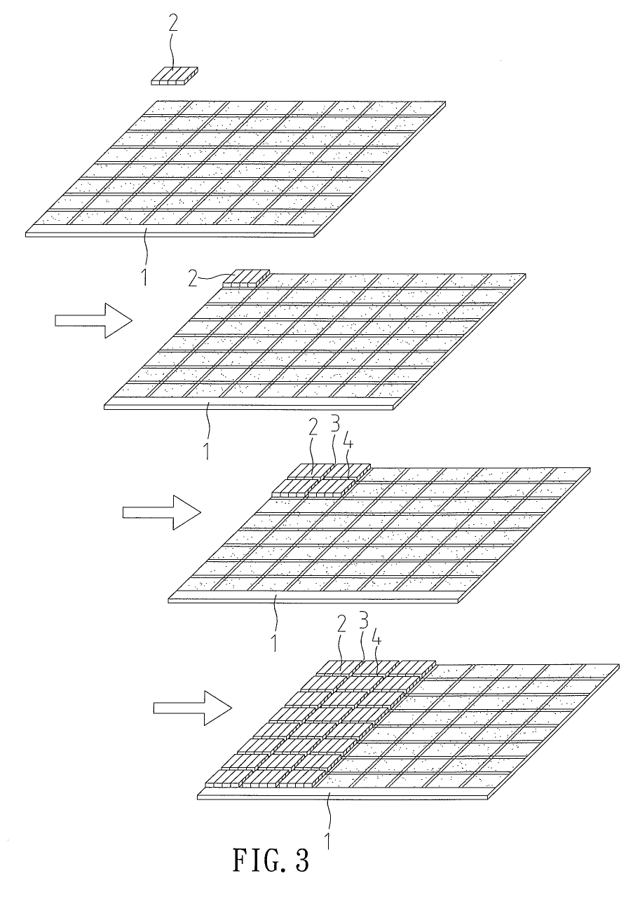

Referring to FIG. 3, it shows a functional flow diagram of the process to form ferrite mosaic in accordance with the preferred embodiment of the present invention. The ferrite mosaic includes the supporting plate 1 and ferrite units 2. The supporting plate 1 is preferably in form of insulating paper, PCB (Printed Circuit Board) plate or ferrite polymer film. The rectangular ferrite units 2 are going to stick on the upper surface of the supporting plate 1 in an array manner. Before sticking the ferrite units 2, according to the overall shape of the magnetic core structure, drawing transverse and longitudinal lines on the supporting plate 1 for positioning the ferrite units 2 thereon, first. And then, the upper surface of the supporting plate 1 is coated with binder and the ferrite units 2 are stuck on the upper surface of the supporting plate 1 along the lines drawn on the supporting plate 1. The transverse and longitudinal air-gaps 3, 4 are provided between the ferrite units 2, and width of each transverse air-gap 3 is equal to that of each longitudinal air-gap 4. Finally, if a single-sided adhesive plastic film (not shown) is used as the supporting plate 1, it would make to produce the ferrite mosaic for a passive substrate much easier.

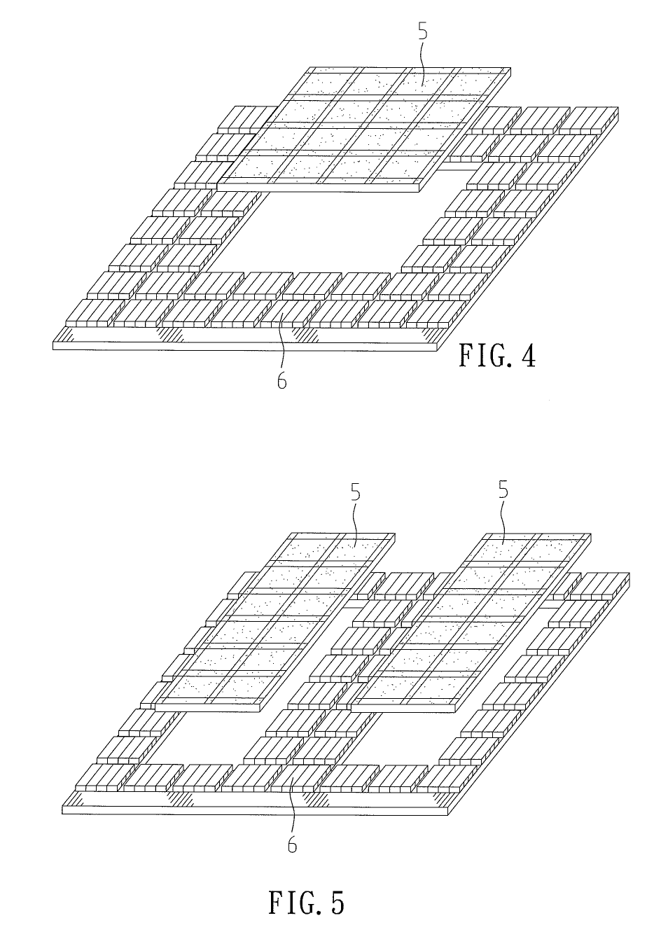

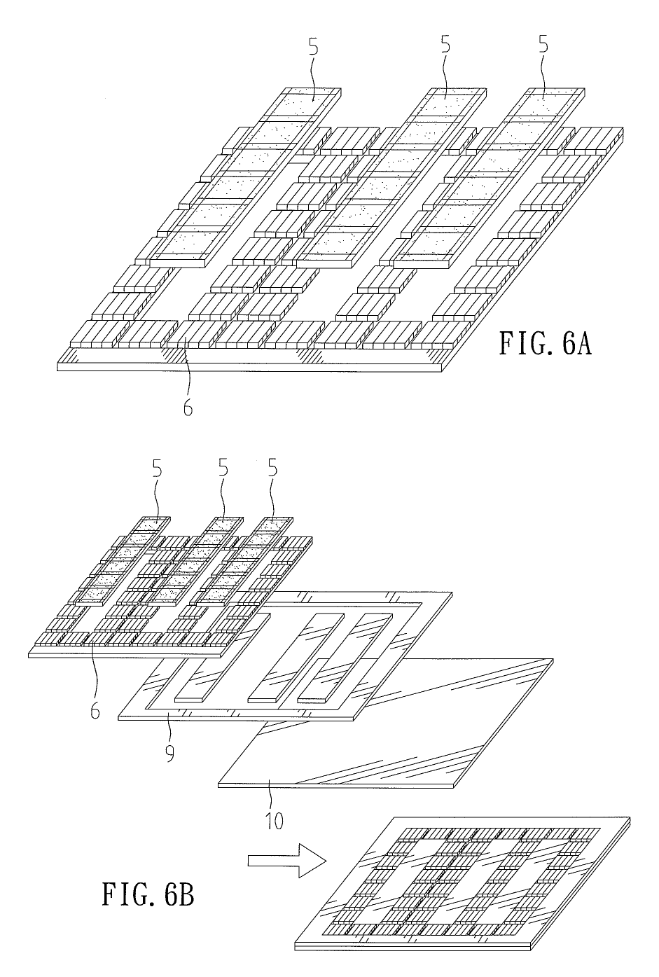

Referring to FIG. 4, it shows a process to produce a horizontal magnetic core structure without center pole. There is a reserve space 5 which is defined on the supporting plate 1. The size and amount of the reserve space 5 is adjustable as desired, further referring to FIGS. 5 and 6(a). For getting a magnetic core structure 6 which has a desired/designed shaped, it could be easy to detach the ferrite units 2 which are stuck on the reserve space 5 from the supporting plate 1 or cut parts of the supporting plate 1 where the reserve space 5 is defined.

Referring to FIG. 6(b), with regard to the finished magnetic core structure 6 as shown in FIG. 6(a), a PCB limiting plate 9 would be produced first. Shape of the PCB limiting plate 9 corresponds to the magnetic core structure 6. Second, the PCB limiting plate 9 is piled onto the PCB base supporting plate 10. Then fix the magnetic core structure 6 into the PCB limiting plate 9. During an installation process, the magnetic core is stably laminated and fixed in the passive substrate with glue.

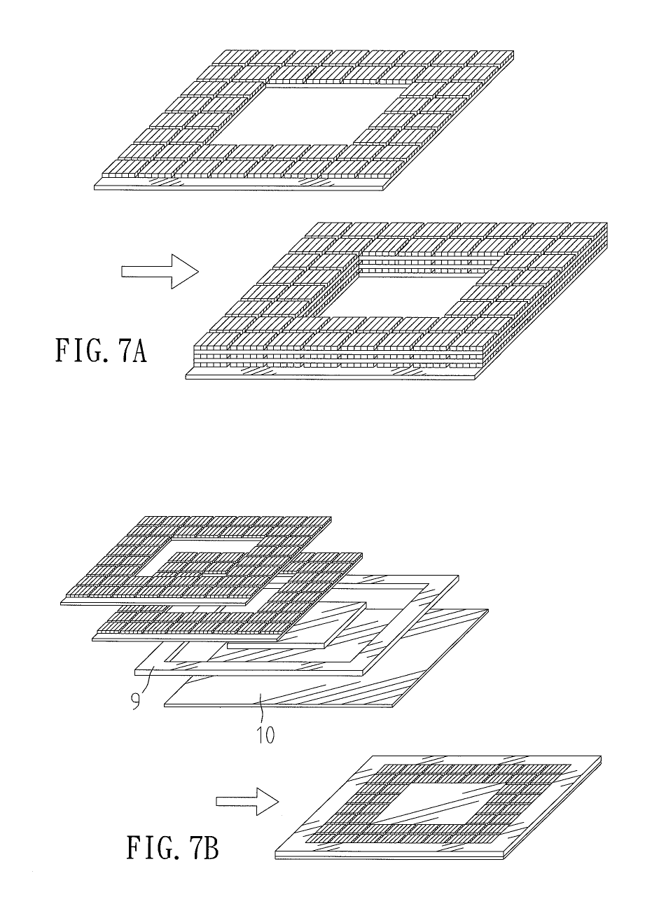

Referring to FIGS. 7(a) and 7(b), it shows a process to produce a multi-layer horizontal magnetic core without center pole. First, three single layer ferrite mosaics with same structure without center pole are produced and then, a piled combination of the three single layer ferrite mosaics is formed as shown in FIG. 7(a). Another PCB limiting plate 9 would be produced further. Shape of the PCB limiting plate 9 corresponds to the laminated combination of the three single layer ferrite mosaics. The PCB limiting plate 9 is piled onto another PCB base supporting plate 10, and then fix the laminated combination of the three single layer ferrite mosaics into the PCB limiting plate 9. During installation, the magnetic core is laminated and fixed inside the passive substrate with glue.

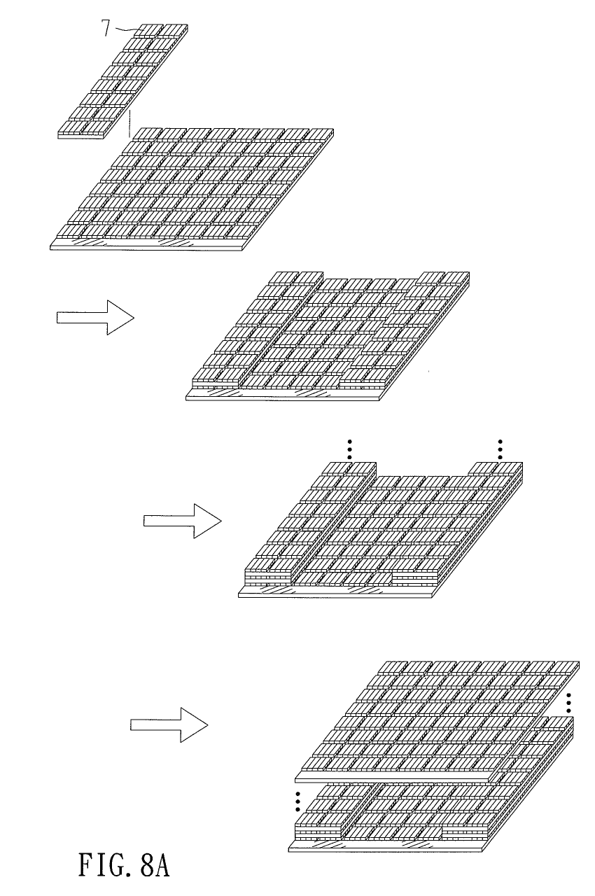

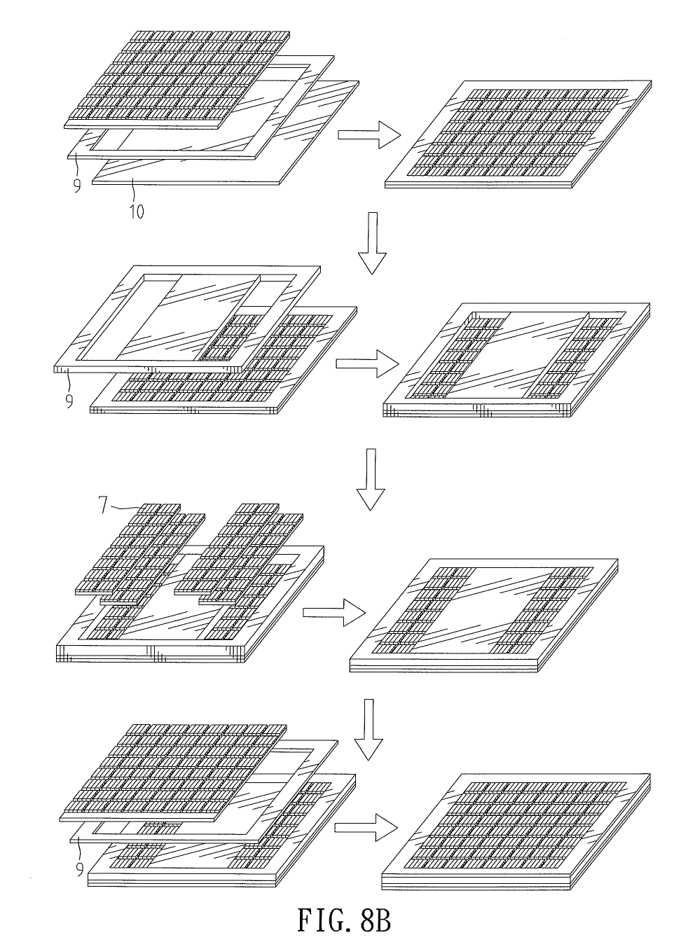

Referring to FIG. 8(a), it shows a process to produce a vertical magnetic core structure without center pole. First, a single layer ferrite mosaic without center pole is produced and used as substrate of the magnetic core structure. Then, several of rectangular side ferrite mosaics 7 are formed by cutting, and the side ferrite mosaics 7 are respectively neatly piled on two sides of upper surface of the substrate of the magnetic core structure. In this case, two of the side ferrite mosaics 7 are piled on each side of the upper surface of the substrate of the magnetic core structure. Finally, another single layer ferrite mosaic without center pole is piled onto the side ferrite mosaics 7 opposite to the substrate and used as a roof substrate of the magnetic core structure for forming a vertical magnetic core structure without center pole.

Referring to FIG. 8(b), with regard to the vertical magnetic core structure without center pole as shown in FIG. 8(a), several of rectangular side ferrite mosaics 7 are formed by cutting, and one PCB limiting plate 9 is produced to correspond to the side ferrite mosaics 7. It is needed to produce two sets of single layer ferrite mosaic without center pole and the corresponded PCB limiting plate 9. Further, one set that is described above is piled on a PCB base supporting plate 10 as the bottom layer, and then the PCB limiting plate 7 corresponding to side ferrite mosaics 7 is piled on said bottom layer. Subsequently, the side ferrite mosaics 7 and another set are piled in position. During installation, the magnetic core is laminated and fixed inside the passive substrate with glue.

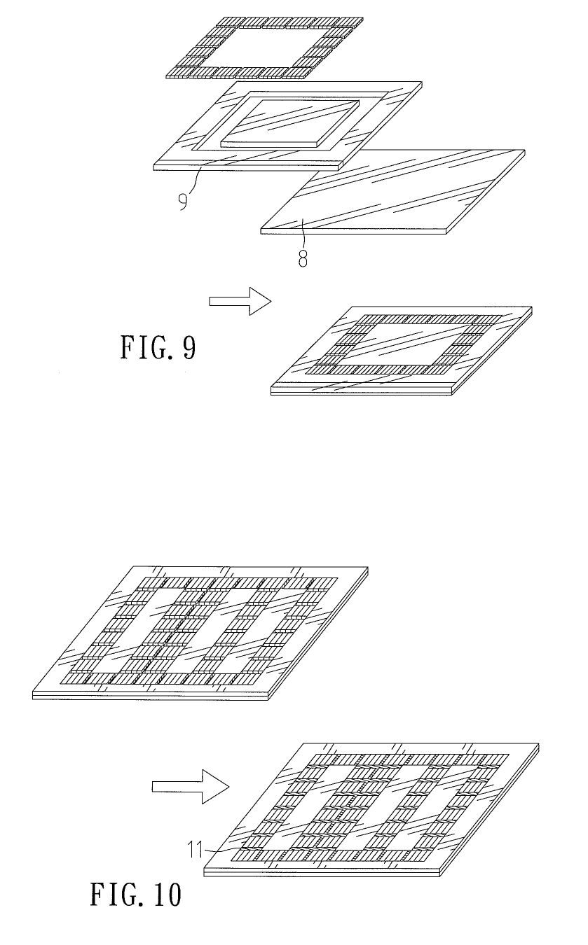

Referring to FIG. 9, it shows a process to produce a single layer horizontal magnetic core without center pole with PCB as the supporting plate. First, according to a desired design of magnetic core structure, a PCB limiting plate 9 is going to be cut and formed to correspond to the desired design of magnetic core structure. Then, the PCB limiting plate 9 is piled on a PCB supporting plate 8. Finally, numbers of ferrite units 2 are stuck on the PCB supporting plate 8 in position and the single layer horizontal magnetic core is finished.

Referring to FIG. 10, it shows a process to produce a horizontal magnetic core with numbers of center poles, and the magnetic core structure includes equivalent small air-gaps. Further regarding to the single layer horizontal magnetic core structure with numbers of center poles as shown in FIG. 6(b), ferrite glue polymer composites 11 are filled into and cured in the air-gaps between the ferrite units 2 of the magnetic core structure as to reduce equivalent air gap length.

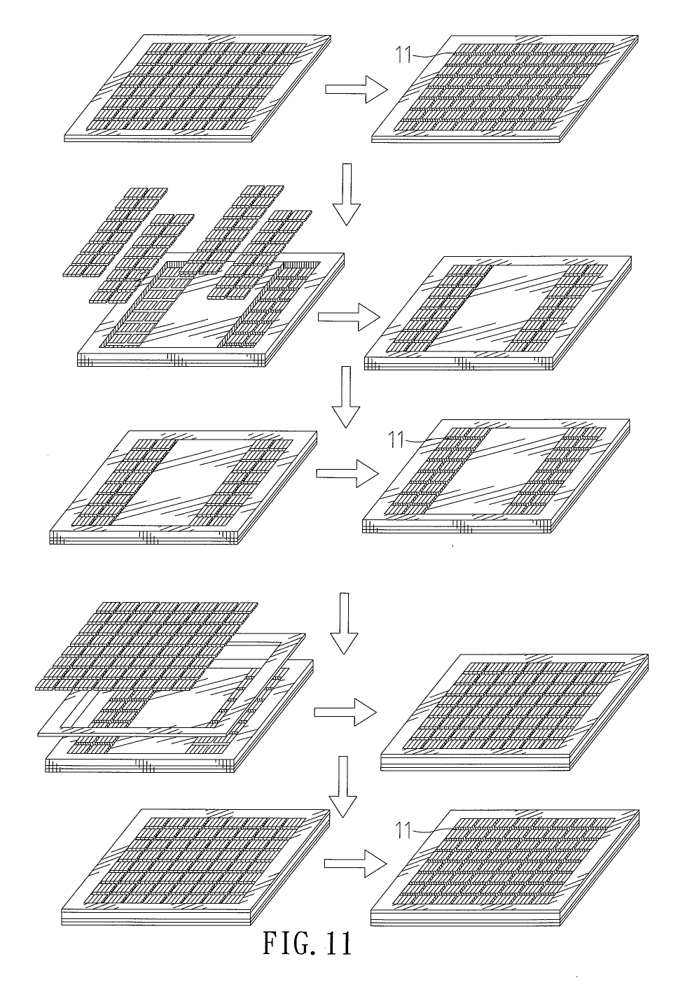

Referring to FIG. 11, it shows a process to produce a vertical magnetic core structure without center pole, and the magnetic core structure includes equivalent small air-gaps. In this case, the difference to the magnetic core shown in 8(b) is that ferrite glue polymer composites 11 are filled into and cured in the air-gaps between the ferrite units 2 of the ferrite mosaic as to reduce equivalent air gap length. Further, except for the bottom layer, the ferrite units at the other layers can be stuck onto the ones at the lower layer rather than onto the supporting plates.

The ferrite glue polymer composites 11 are mixture of ferrite powders and epoxy polymer resin or mixture of ferrite powders and organic silicon polymer. Mixing the ferrite powders and the epoxy polymer resin or the organic silicon polymer in varying proportions, it can get ferrite glue polymer composites having different average permeability. Filling this kind of ferrite glue polymer composites into the air-gaps between the ferrite units, due to the average permeability more than 1, the equivalent air gap length would be reduced in proportion. Although the losses of the ferrite glue polymer composites are relatively higher than sintered ferrite, it contributes little to the whole losses of the magnetic component because of their small volume.

During manufacturing the ferrite glue polymer composites, granularity of ferrite powders is smaller than 10 micron and the ferrite powders are preferably MnZn or NiZn ferrite powder. These powders are produced by milling and screening the sintered MnZn or NiZn ferrite. Epoxy polymer resin and organic silicon polymer are needed to be cured quickly at normal temperatures. The epoxy polymer resin is able to be TW GXHY-104 adhesive (Xi'An Towin Telecommunication Technologies Co., Ltd) or high-temperature epoxy adhesive KH0201 (Institute of Chemistry Chinese Academy of Sciences). The organic silicon polymer is able to be KH-SP-RTV silicone rubber (Institute of Chemistry Chinese Academy of Sciences). As an example to TW GXHY-104 adhesive, it consists of two sets adhesives A and B. At room temperature, mixing adhesives A and B in varying proportions can get mixture adhesive with different consistency. In this case, mixing ratio of volume of adhesive A to volume of adhesive B is 2. This mixture adhesive will maintain a thin glue state till 12 hours at room temperature. In addition, if this mixture adhesive is heated to 60 degrees Celsius, it would be cured in 30 minutes.

There are two methods for mixing the ferrite powder and polymers to form ferrite glue polymer composites: (a) first, respectively mixing ferrite powder and the adhesives A and B; second mixing the mixture of ferrite powder and the adhesive A and the mixture of ferrite powder and the adhesive B; b) first, mixing the adhesives A and B; second, mixing ferrite powder and the mixture of the adhesives A and B.

After the mixture of ferrite glue polymer composites is finished, referring to FIG. 11, filling the finished ferrite glue polymer composites into the air-gaps between the ferrite units at the bottom layer. Then, the exceeded ferrite glue polymer composites have to be removed from the surface of the ferrite units and heated to 60 degrees Celsius. Hence, in 30 minutes, the ferrite glue polymer composites are cured in the air-gaps. The following is pilling a limiting plate on the bottom layer and pilling side supporting plates 7 which only consist of ferrite units. Then, the finished ferrite glue polymer composites are filled into the air-gaps between the ferrite units of the side supporting plates 7. The same, the exceeded ferrite glue polymer composites have to be removed from the surface of the ferrite units and heated to 60 degrees Celsius. And the final step is pilling a limiting plate on the piled side supporting plates 7 and pilling a top substrate which has been described in 8(b). Then, the finished ferrite glue polymer composites which are filled into the air-gaps between the ferrite units on the top supporting plate is going to be heated and cured.

The ferrite units can also be stuck on the supporting plate, and the ferrite glue polymer composites are filled into and cured in the air-gaps first as to form a ferrite mosaic. And further by cutting, pilling and joining the finished ferrite mosaics forms a desired magnetic core structure. Alternatively, ferrite units can also be stuck on the supporting plate, and by cutting, pilling and joining the finished ferrite mosaics forms a desired magnetic core structure. And further the ferrite glue polymer composites are filled into and cured in the air-gaps as to form a finished ferrite mosaic. And further by pilling and joining the finished ferrite mosaics forms a desired magnetic core structure.

While several embodiments of the invention have been shown and described, it will be apparent to those skilled in the art that modifications may be made therein without departing from the scope and spirit of the present invention.

What is claimed is:

1. A ferrite mosaic for passive substrate for switched-mode power supply module, the ferrite mosaic comprising: a supporting plate and numbers of ferrite units and air-gaps defined between the ferrite units; wherein said ferrite units are attached onto the supporting plate, with each ferrite unit being rectangular. Said air-gaps are filled and cured with ferrite glue polymer composites.

2. The ferrite mosaic as claimed in claim 1, wherein the ferrite glue polymer is a mixture of ferrite powders and epoxy polymer resin.

3. The ferrite mosaic as claimed in claim 1, wherein the ferrite glue polymer is a mixture of ferrite powders and organic silicon polymer.

4. The ferrite mosaic as claimed in claim 1, wherein the supporting plate is plastic film.

5. The ferrite mosaic as claimed in claim 1, wherein the supporting plate is insulation paper.

6. The ferrite mosaic as claimed in claim 1, wherein the supporting plate is PCB plate.

7. The ferrite mosaic as claimed in claim 1, wherein the supporting plate is ferrite polymer film.

8. The ferrite mosaic as claimed in claim 1, wherein each ferrite unit has upper and lower surfaces which are both square.

9. The ferrite mosaic as claimed in claim 1, wherein width of each transverse air-gap is equal to that of each longitudinal air-gap.

10. The magnetic core structure for passive substrate for switched-mode power supply module as claimed in any of claims 1 through 9, wherein the magnetic core structure for passive substrate is formed by cutting, laminating and assembling the ferrite mosaics.
